(19) United States
(12) Patent Application Publication
(10) Pub. No.: US 2026/0123237 A1
(43) Pub. Date: Apr. 30, 2026

(54) DISPLAY DEVICE

(71) Applicant: LG Display Co., Ltd., Seoul (KR)

(72) Inventors: Seung Han PAEK, Paju-si (KR); Yong In PARK, Paju-si (KR); Hyun Jin AN, Paju-si (KR); Kyung Jae YOON, Paju-si (KR); Jeon Phill HAN, Paju-si (KR)

(73) Assignee: LG Display Co., Ltd., Seoul (KR)

(21) Appl. No.: 19/003,308

(22) Filed: Dec. 27, 2024

(30) Foreign Application Priority Data
Dec. 29, 2023 (KR) 10-2023-0197380

(51) Int. Cl. H10K 59/80; H10K 59/12; H10K 59/127

(52) U.S. Cl. CPC H10K 59/871; H10K 59/1201; H10K 59/1275

(57) ABSTRACT

A display device having a first side and a second side may include a first substrate having an end portion, a first etch-stop layer having an end portion, a circuit layer and light emitting layer, a second substrate, and a second etch-stop layer. The first etch-stop layer may be disposed on the first substrate and the light emitting layer may be disposed on the first etch-stop layer. The second substrate may be disposed on the light emitting layer and the second etch-stop layer may be disposed between the second substrate and the light emitting layer. The end portion of the first etch-stop layer may protrude further in a direction fo the first side of the display device than the end portion of the first substrate.

### CROSS-REFERENCE TO RELATED APPLICATION

This application claims priority to and the benefit of Korean Patent Application No. 10-2023-0197380, filed on Dec. 29, 2023, the disclosure of which is incorporated herein by reference in its entirety.

### BACKGROUND

### Field of the Invention

The present specification relates to a display device.

### Discussion of Related Art

Electroluminescence display devices may be classified into inorganic light emitting display devices and organic light emitting display devices depending on a material of a light emitting layer. Active-matrix type organic light emitting diode display devices include organic light emitting diodes (hereinafter referred to as “OLEDs”) that emit light by itself and have advantages of having a fast response time, high luminous efficiency and brightness, a wide viewing angle. An OLED display device includes OLEDs formed in each pixel. Since the OLED display device has a fast response time, high luminous efficiency and brightness, and a wide viewing angle and may express a black gradation in perfect black, the OLED display device has an excellent contrast ratio and a high color gamut.

A cover glass generally applied to the OLED may be used to protect a thin film encapsulation (TFE) structure for preventing moisture permeation from the outside. The cover glass has high strength but its manufacturing costs are high, and thus is not always be suitable for uniform application to all products. For example, since the strength of the cover glass required in a mobile device is higher than strength required in a notebook device, it may be uneconomical to apply the cover glass applied to the mobile device to the notebook device. Therefore, it is advantageous to distinguish a component in which a structure for protecting the TFE for each model (e.g., mobile products, wearable devices, TVs, or notebook computers) using a display device is formed.

### SUMMARY OF THE INVENTION

Accordingly, embodiments of the present disclosure are directed to a display device that substantially obviates one or more of the problems due to limitations and disadvantages of the related art.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described,.

According to certain embodiments, a display device having a first side opposite a second side, the display device may include a first substrate having an end portion, a first etch-stop layer having an end portion disposed on the first substrate, a circuit layer and a light emitting element layer disposed on the first etch-stop layer, a second substrate disposed on the light emitting element layer, and a second etch-stop layer disposed between the second substrate and the light emitting element layer. The end portion of the first etch-stop layer may protrude further in a direction of the first side than the end portion of the first substrate.

In some embodiments, the display device of claim may further include a coating layer disposed on the end portion the substrate.

In some embodiments, the second substrate may be positioned above the second etch-stop layer in a vertical direction.

In some embodiments, the end portion of the substrate may be tapered, and an end portion of the coating layer may be tapered such that the end portion of the coating layer corresponds to the end portion of the substrate.

In some embodiments, the display device may further include a first side surface and a second side surface that face each other, a third side surface and a fourth side surface that face each other. The first substrate may include a 5^{th} side portion and a 6^{th} side portion that are disposed on the first side surface and the second side surface, respectively, and face each other. A 7^{th} side portion and an 8^{th} side portion may be disposed on the third side surface and the fourth side surface, respectively, and face each other. The second substrate may include a 9^{th} side portion and a 10^{th} side portion that are disposed on the first side surface and the second side surface, respectively, and face each other. An 11^{th} side portion and a 12^{th} side portion may be disposed on the third side surface and the fourth side surface, respectively, and face each other.

In some embodiments, the first etch-stop layer may include a 13^{th} side portion and a 14^{th} side portion that are disposed on the first side surface and the second side surface, respectively, and face each other. A 15^{th} side portion and a 16^{th} side portion may be disposed on the third side surface and the fourth side surface, respectively, and face each other.

In some embodiments, the second etch-stop layer may include a 17^{th} side portion and an 18^{th} side portion that are disposed on the first side surface and the second side surface, respectively, and face each other. A 19^{th} side portion and a 20^{th} side portion may be disposed on the third side surface and the fourth side surface, respectively, and face each other.

In some embodiments, the 5^{th} side portion and the 13^{th} side portion may be disposed to overlap each other in a thickness direction. The 6^{th} side portion and the 14^{th} side portion may be disposed to overlap each other in the thickness direction. The 7^{th} side portion and the 15^{th} side portion may be disposed to overlap each other in the thickness direction. The 8^{th} side portion and the 16^{th} side portion may be disposed to overlap each other in the thickness direction.

In some embodiments, the 9^{th} side portion and the 17^{th} side portion may be disposed to overlap each other in the thickness direction. The 10^{th} side portion and the 18^{th} side portion may be disposed to overlap each other in the thickness direction. The 11^{th} side portion and the 19^{th} side portion may be disposed to overlap each other in the thickness direction. The 12^{th} side portion and the 20^{th} side portion may be disposed to overlap each other in the thickness direction.

In some embodiments, the 13^{th} side portion and the 17^{th} side portion may be positioned such that they are misaligned in a thickness direction. The 14^{th} side portion and the 18^{th} side portion may be disposed to overlap each other in the thickness direction. The 15^{th} side portion and the 19^{th} side portion may be disposed to overlap each other in the thickness direction. The 16^{th} side portion and the 20^{th} side portion may be disposed to overlap each other in the thickness direction.

In some embodiments, the first etch-stop layer may have a ring structure and may be disposed to overlap an area disposed outside the first substrate. The second etch-stop layer may have a ring structure and is disposed to overlap an area disposed outside the second substrate.

In some embodiments, the first etch-stop layer may have a planar structure and may be disposed to overlap an area disposed inside the first substrate.

In some example embodiments, the first substrate includes a first area and a second area. The second substrate and the second etch-stop layer may be disposed on the first area, and the first etch-stop layer may be disposed on the first area and the second area.

In some embodiments, the 13^{th} side portion may be disposed on the second area, and the 17^{th} side portion may be disposed on the first area.

In some embodiments the display device may further include a bonding layer disposed between the second substrate and the first substrate.

In some embodiments, the bonding layer includes a 21^{st} side portion disposed between the 18^{th} side portion and the 14^{th} side portion.

In some embodiments, a thickness of the 21^{st} side portion is greater than a thickness of the bonding layer and disposed to overlap the light emitting element layer.

In some embodiments the display device further includes a back surface coating layer formed on a back surface of the first substrate.

In some embodiments the display device further includes a first side surface coating layer disposed at a first side and disposed at the 5^{th} side portion so as to overlap the 13^{th} side portion, a first side surface coating layer disposed at a second side and disposed at the 6^{th} side portion so as to overlap the 14^{th} side portion, a first side surface coating layer disposed at a third side and disposed at the 7^{th} side portion so as to overlap the 15^{th} side portion, and a first side surface coating layer disposed at a fourth side and disposed at the 8^{th} side portion so as to overlap the 16^{th} side portion.

In some embodiments, the 13^{th} side portion includes a protrusion protruding toward the first side surface. The 14^{th} side portion may include a protrusion protruding toward the second side surface. The 15^{th} side portion may include a protrusion protruding toward the third side surface. The 16^{th} side portion may include a protrusion protruding toward the fourth side surface.

In some embodiments, the 17^{th} side portion may include a protrusion protruding toward the first side surface. The 18^{th} side portion may include a protrusion protruding toward the second side surface. The 19^{th} side portion may include a protrusion protruding toward the third side surface. The 20^{th} side portion may include a protrusion protruding toward the fourth side surface.

In some embodiments, a size of the second substrate is greater than a size of the first substrate.

In some embodiments, the 9^{th} side portion may include a protrusion protruding toward the 5^{th} side portion.

According to certain embodiments, a display device having a first side opposite a second side, the display device including a first substrate having an end portion, a first etch-stop layer having an end portion disposed on the first substrate. a circuit layer and a light emitting element layer disposed on the first etch-stop layer, a second substrate disposed on the light emitting element layer, a second etch-stop layer disposed between the second substrate and the light emitting element layer, and a coating layer disposed the end portion of the first substrate and the end portion of the second substrate. The end portion of the first etch-stop layer may protrudes further in a direction of the first side than the end portion of the first substrate.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view showing a display device according to an embodiment of the present disclosure.

FIG. 2 is an exploded perspective view showing the display device according to an embodiment of the present disclosure.

FIG. 3 is a cross-sectional view along line I-I′ in FIG. 1, which shows a display device according to a first embodiment of the present disclosure.

FIG. 4 is a cross-sectional view along line I-I′ in FIG. 1, which shows a display device according to a second embodiment of the present disclosure.

FIG. 5 is a cross-sectional view along line I-I′ in FIG. 1, which shows a display device according to a third embodiment of the present disclosure.

FIG. 6 is a cross-sectional view along line II-II′ in FIG. 1, which shows the display device according to the first embodiment of the present disclosure.

FIG. 7 is a cross-sectional view along line II-II′ in FIG. 1, which shows the display device according to the third embodiment of the present disclosure.

FIG. 8 is a cross-sectional view along line I-I′ in FIG. 1, which shows a display device according to a fourth embodiment of the present disclosure.

FIG. 9 is a cross-sectional view along line I-I′ in FIG. 1, which shows a display device according to a fifth embodiment of the present disclosure.

FIG. 10 is a cross-sectional view along line I-I′ in FIG. 1, which shows a display device according to a sixth embodiment of the present disclosure.

FIG. 11 is a cross-sectional view showing a substrate of the display device according to an embodiment of the present disclosure.

FIG. 12 is a plan view showing a mother substrate according to an embodiment of the present disclosure.

FIG. 13 is a view for describing an etching process in a method of manufacturing a display device according to an embodiment of the present disclosure.

FIG. 14 is a view for describing an etching process in a method of manufacturing a display device according to another embodiment of the present disclosure.

FIGS. 15 to 26 are views for describing the method of manufacturing the display device according to an embodiment of the present disclosure.

### DETAILED DESCRIPTION OF EXEMPLARY EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

In describing the present disclosure, the same reference number indicates the same components throughout the specification.

When the terms “comprises,” “includes,” “has,” and “consists of” described in the present disclosure are used, other parts may be added unless “only” is used. When a component is expressed in the singular, it can be construed as a plurality of components unless specifically stated otherwise.

When the position relationship and interconnection relationship between two components, such as “on,” “above,” “under,” “next to,” “connected or coupled,” “crossing or intersecting,” or the like described, one or more other components may be interposed between the components unless the term “immediately”or “directly”is described.

When the temporal relationship is described using the term “after,” “subsequently,” “then,” “before,” or the like, it may include a non-consecutive case unless the term “immediately” or “directly” is used. Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

The following embodiments may be partially or fully coupled or combined, and various technological interworking and driving are possible. The embodiments may be implemented independently of each other and implemented together in the associated relationship.

In addition, terms (including technical and scientific terms) used in embodiments of the present disclosure may be construed as meaning that may be generally understood by those skilled in the art to which the present specification pertains unless explicitly specifically defined and described, and the meanings of the commonly used terms, such as terms defined in a dictionary, may be construed in consideration of contextual meanings of related technologies.

Hereinafter, embodiments of the present invention will be described in detail with reference to the accompanying drawings.

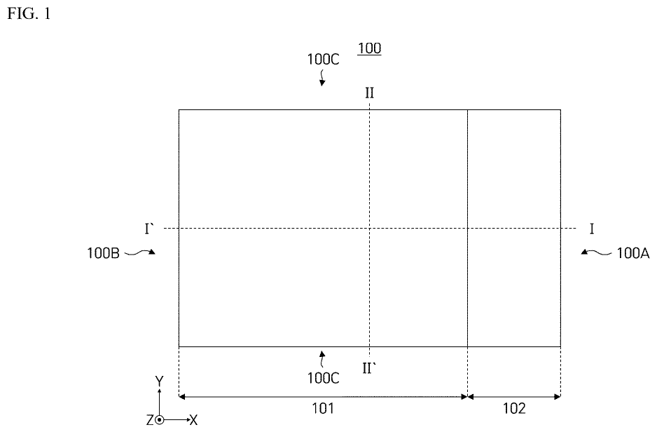

As shown in FIG. 1, a display device 100 may include a first side surface 100A and a second side surface 100B that face each other, and a third side surface 100C and a fourth side surface 100D that face each other. The display device 100 may include a first area 101 and a second area 102. The first area 101 may be a display area. The second area 102 may be an integrated circuit (IC) area where a driving IC for driving the first area 101 is disposed. However, the present disclosure is not limited thereto, and the second area 102 may be a sub-display area.

A bending portion (not shown) may be formed between the first area 101 and the second area 102. In a plan view, the bending portion may be formed with a bending line extending in one direction. The first area 101 and the second area 102 may be bent at a predetermined angle with respect to the bending line.

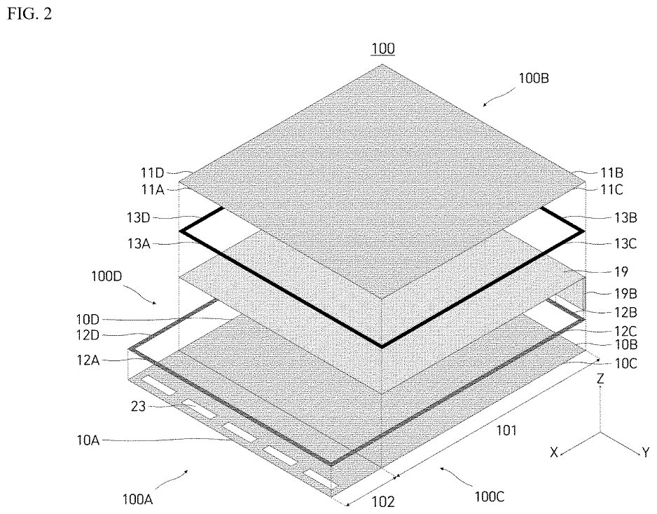

As shown in FIG. 2, the display device 100 may be manufactured so as to comprise substrates 10 and 11. The display device 100 may include a lower substrate 10 (or a first substrate), a pad 23 disposed on the lower substrate 10, a lower organic film 12 (or a first etch-stop layer) disposed on the lower substrate 10, a bonding layer 19 disposed on the lower organic film 12, an upper organic film 13 (or a second etch-stop layer) disposed on the bonding layer 19, and an upper substrate 11 (or a second substrate) disposed on the upper organic film 13.

The display device 100 may have, for example, a width in an X-axis direction, a length in a Y-axis direction, and a constant thickness in a Z-axis direction. Since a circuit layer and a light emitting element layer may be disposed on the lower substrate 10, the thickness of the display device 100 may be greater than the thicknesses of the substrates 10 and 11. The width and length of the display device 100 may be set to various design values according to application fields of the display device 100. The display device 100 may be manufactured in a substantially rectangular and quadrangular plate shape, but is not limited thereto. For example, the display device 100 may be formed of a different shaped panel including having curved portions.

When a bending portion is formed between the first area 101 and the second area 102 of the display device 100, an organic film including an organic material may be formed on at least a portion of the bending portion so that the display device 100 may be easily bent at the bending portion. The organic material may comprise one or a mixture of two or more highly elastic resin materials, such as polyimide, polyurethane, acrylic, and silicone synthetic rubber, may be applied. For example, in some embodiments, the silicone synthetic rubber may include polydimethylsiloxane (PDMS).

One or more of the first and second areas 101 and 102, respectively, may include a display area where input images can be reproduced. The first and second areas 101 and 102, respectively, may be sized such that the first and second areas 101 and 102, respectively, have different sizes. For example, in some embodiments, the first area 101 may include a pixel array on which images are displayed, and the second area 102 may include an IC mounting area where a driving IC for driving the pixels is mounted. A pad 23 may be disposed in the IC mounting area. The pad 23 may be connected to an external circuit (not shown).

In some embodiments, the first area 101 may include the pixel array on which the images are displayed, and at least a portion of the second area 102 may include a pixel array which displays images or preset additional information.

As described above, the display device 100 may include the first side surface 100A and the second side surface 100B that face each other, and the third side surface 100C and the fourth side surface 100D that face each other. Components included in the display device 100 may be understood as components disposed on the first to fourth side surfaces 100A, 100B, 100C, and 100D, respectively.

The lower substrate 10 may include a first side lower substrate 10A (also referred to as the “5^{th} side portion”) disposed on the first side surface 100A, a second side lower substrate 10B (also referred to as the “6^{th} side portion”) disposed on the second side surface 100B, a third side lower substrate 10C (also referred to as the “7^{th} side portion”) disposed on the third side surface 100C, and a fourth side lower substrate 10D (also referred to as the “8^{th} side portion”) disposed on the fourth side surface 100D of the display device 100. The second display area may be positioned in the first side lower substrate 10A, but is not limited thereto.

The lower organic film 12 may include a first side lower organic film 12A (also referred to as the “13^{th} side portion”) disposed on the first side surface 100A, a second side lower organic film 12B (also referred to as the “14^{th} side portion”) disposed on the second side surface 100B, a third side lower organic film 12C (also referred to as the “15^{th} side portion”) disposed on the third side surface 100C, and a fourth side lower organic film 12D (also referred to as the “16^{th} side portion”) disposed on the fourth side surface 100D of the display device 100. The first side lower organic film 12A may overlap the first side lower substrate 10A when viewed from a top view (e.g., an XY direction) of the display device 100. The second side lower organic film 12B may overlap the second side lower substrate 10B when viewed from a top view of the display device 100. The third side lower organic film 12C may overlap the third side lower substrate 10C when viewed from a top view of the display device 100. The fourth side lower organic film 12D may overlap the fourth side lower substrate 10D when viewed from a top view of the display device 100.

The lower organic film 12 may be formed in a ring structure such that the lower organic film 12 extends around an outer perimeter of the lower substrate 10. However, the lower organic film 12 is not limited thereto and may be formed in any suitable structure, such as a planar structure. Moreover, the bonding layer 19 may be formed in a planar structure and disposed so as to overlap the inside of the lower substrate 10. The lower organic film 12 may be configured to stop etching as will be described in further detail below. The lower organic film 12 may be formed to overlap the inside of the lower substrate 10 in a range in which the function is performed. The lower organic film 12 may further be capable of distinguishing display devices 100 during the etching and cutting processes of a mother substrate. As such, the lower organic film 12 may be formed in a ring structure. Therefore, it may be possible to reduce the cost for forming the lower organic film 12, thereby reducing the manufacturing cost of the display device 100.

The bonding layer 19 may include a second side bonding layer 19B (also referred to as the “21^{st} side portion”) disposed on the second side surface 100B of the display device 100. However, the bonding layer 19 is not limited thereto and, in some embodiments, may further include a third side bonding layer disposed on the third side surface 100C of the display device 100 and a fourth side bonding layer disposed on the fourth side surface 100D of the display device 100. Although not shown in the figures, a circuit layer and a light emitting element layer may be formed on the first area 101 of the lower substrate 10. The circuit layer and the light emitting element layer may be formed in an inner area of the lower substrate 10 and may be positioned such that they do not overlap an outer area of the lower substrate 10. The bonding layer 19 may be an adhesive for bonding the upper substrate 11 and the lower substrate 10. In some embodiments, the bonding layer 19 may be formed to have a constant thickness (e.g., in the Z direction) in the inner area where the light emitting element layer and the circuit layer are formed. In some embodiments, a thickness of the bonding layer 19 formed in the outer area may be greater than a thickness of the bonding layer 19 formed in the inner area. In some embodiments, when the light emitting element layer and the like are not formed in the outer area, the bonding layer 19 may be formed to have a relatively greater thickness in the inner area for securing stability of the display device 100 by bonding the upper substrate 11 and the lower substrate 10.

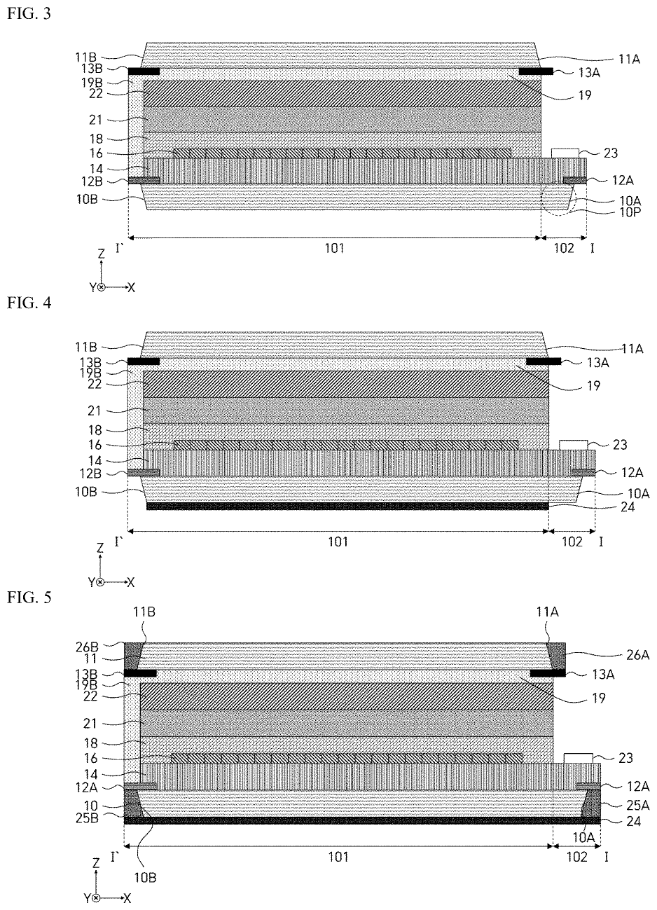

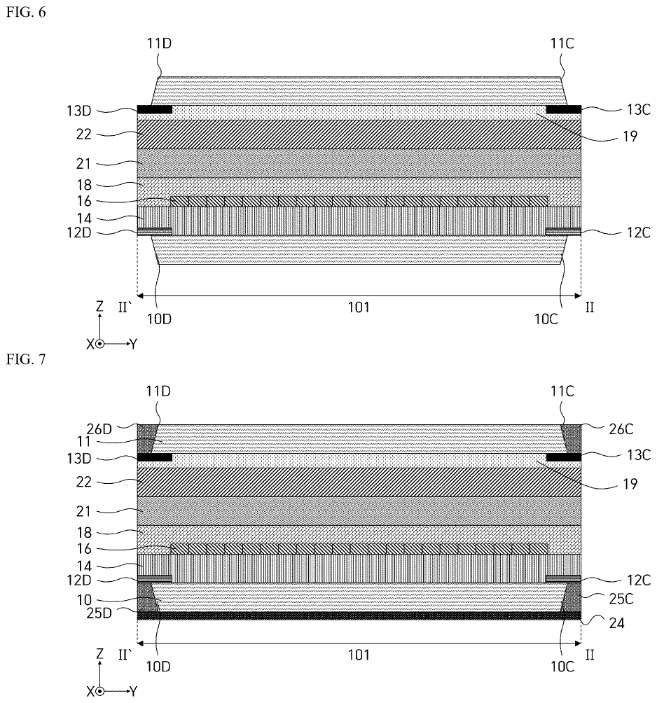

In some embodiments, as shown in FIGS. 3-8, the second side bonding layer 19B may be comprise a relatively greater thickness than that of the bonding layer 19 and may be disposed on the second side surface 100B of the display device 100. However, in other embodiments, the second side bonding layer 19B with a relatively greater thickness is not limited thereto and may be formed on any side surface that allows the upper glass 11 and the lower glass 10 to be laminated firmly. The second side bonding layer 19B may overlap the second side lower organic film 12B and the second side lower substrate 10B when viewed from a top view of the display device 100. In some embodiments, the second side bonding layer 19B may overlap at least a portion of the second side lower organic film 12B. In other embodiments, the second bonding layer 19B may be disposed so as to completely overlap the second side lower organic film 12B. In some embodiments, a length of the second side lower organic film 12B in a first direction (e.g., X direction) may be greater than a length of the second side bonding layer 19B in the first direction.

As described above, in some embodiments, the bonding layer 19 may be formed in a ring structure. In other embodiments, the bonding layer 19 may be formed as a planar structure which fully surrounds the inside in a range in which the function is performed.

In some embodiments, the bonding layer 19 may overlap the first area 101 when viewed from a top view and may not overlap the second area 102 thereby allowing an upper portion of the pad 23 to remain open for connecting to an external circuit. A first side of the bonding layer 19 may overlap a first side upper organic film 13A, and a length of the first side upper organic film 13A may be greater than that of the bonding layer 19 in a first direction. For example, when the first area 101 is considered as the display area, the entirety of the outside of the display area may overlap the upper organic film 13, and the bonding layer 19 may overlap the inside of the display area 101 where images are displayed.

The upper organic film 13 may include a first side upper organic film 13A (also referred to as the “17^{th} side portion”) disposed on the first side surface 100A, a second side upper organic film 13B (also referred to as the “18^{th} side portion”) disposed on the second side surface 100B, a third side upper organic film 13C (also referred to as the “19^{th} side portion”) disposed on the third side surface 100C, and a fourth side upper organic film 13D (also referred to as the “20^{th} side portion”) disposed on the fourth side surface 100D of the display device 100. The upper organic film 13 may have a symmetrical relationship with the lower organic film 12 and may be formed in a ring structure similar to the lower organic film 12. However, the upper organic film 13 is not limited thereto and may be formed in a planar structure to overlap the inner area. The overall structure of the organic film may be selected based on the requirements and desires of a developer.

The upper organic film 13 may be formed to overlap an outer perimeter of the first area 101 when viewed from a top view of the display device 100. The upper organic film 13 may be configured to distinguish the display devices 100 in the etching and cutting processes of the mother substrate. Therefore, in some embodiments, the upper organic film 13 may be formed in the ring structure. Therefore, it may be possible to reduce the manufacturing cost of the display device 100.

The upper substrate 11 may include a first side upper substrate 11A (also referred to as the “9^{th} side portion”) disposed on the first side surface 100A, a second side upper substrate 11B (also referred to as the “10^{th} side portion”) disposed on the second side surface 100B, a third side upper substrate 11C (also referred to as the “11^{th} side portion”) disposed on the third side surface 100C, and a fourth side upper substrate 11D (also referred to as the “12^{th} side portion”) disposed on the fourth side surface 100D of the display device 100. In some embodiments, when the first area 101 is considered as the display area, the upper substrate 11 may overlap the display area. The second side upper substrate 11B may overlap the second side lower substrate 10B, the second side bonding layer 19B, and the second side upper organic film 13B in the top view of the display device 100.

As shown in FIGS. 3 to 7, the display device 100 may include the lower substrate 10 (also referred to as the first substrate), the lower organic film 12 (also referred to as the first etch-stop layer) disposed on the lower substrate 10, circuit layers 14 sequentially stacked on the lower organic film 12, a light emitting element layer 16, an encapsulation layer 18 covering the light emitting element layer 16, the bonding layer 19 disposed on the encapsulation layer 18 to be in close contact with the upper substrate 11, an upper organic film 13 (also referred to as the second etch-stop layer) disposed between the bonding layer 19 and the upper substrate 11, and the upper substrate 11 (also referred to as the the second substrate) laminated by the bonding layer 19. The display device 100 may further include a touch sensor layer 21 and a color filter layer 22 disposed on the encapsulation layer 18.

Each of the lower substrate 10 and the upper substrate 11 may be formed of an alkali glass, a plate-shaped alkali-free glass, a non-alkali glass, a tempered glass, or the like. The lower substrate 10 and the upper substrate 11 may be manufactured based on a bendable glass film substrate. The glass film substrate may be a glass film having a thickness of 0.2 mm or less. In some embodiments, the glass film can be formed from a commercially available tempered glass film.

In some embodiments, the lower substrate 10 may be larger than the upper substrate 11. The lower substrate 10 may include the first area 101 and the second area 102, and the upper substrate 11 may be formed in the first area 101 of the lower substrate 10. The pad 23 may be disposed in an area of the lower substrate 10 which does not overlap the upper substrate 11. For example, the pad 23 may be disposed in the second area 102. The lower substrate 10 may include a protrusion 10P of the lower substrate 10, which extends in a direction toward the first side 100A of the display device 100. The protrusion 10P may protrude further toward the first side 100A as compared to the upper substrate 11.

In some embodiments, the thickness of each of the lower substrate 10 and the upper substrate 11 may be 500 μm or less. In other embodiments, thickness of each of the lower substrate 10 and the upper substrate 11 may be 300 μm or less. In yet further embodiments, the thickness of each of the lower substrate 10 and the upper substrate 11 may be 200μm or less. The thickness may be adjusted through an etching process as will be described below.

Each of the lower substrate 10 and the upper substrate 11 may include tapered surfaces 10A, 10B, 10C, 10D, 11A, 11B, 11C, and 11D disposed on the first to fourth sides of each of the lower substrate 10 and the upper substrate 11. The tapered surface may be an inclined surface. In some embodiments, the tapered surface may be a linearly inclined surface, but may include any one of cross sections which may be formed by an etching fluid in the etching process as will be described below. For example, in some embodiments, the tapered surface may include a wedge shape. However, the tapered surface may include any suitable shape based on requirements and desires of the developer.

The lower tapered surface may include a first side lower tapered surface 10A, a second side lower tapered surface 10B, a third side lower tapered surface 10C, and a fourth side lower tapered surface 10D.

The upper tapered surface may include a first side upper tapered surface 11A, a second side upper tapered surface 11B, a third side upper tapered surface 11C, and a fourth side upper tapered surface 11D.

The first side lower tapered surface 10A1 formed on the first side lower substrate 10A may overlap the first side lower organic film 12A. The second side lower tapered surface 10B1 formed on the second side lower substrate 10B1 may overlap the second side lower organic film 12B. The third side lower tapered surface 10C1 formed on the third side lower substrate 10C may overlap the third side lower organic film 12C. The fourth side lower tapered surface 10D1 formed on the fourth side lower substrate 10D may overlap the fourth side lower organic film 12D. A resulting shape surrounded by each of the lower tapered surfaces 10A1, 10B1, 10C1, and 10D1 and each of the lower organic films 12A, 12B, 12C, and 12D may be shaped such that it includes a tapered shape

The first side upper tapered surface 11A1 formed on the first side upper substrate 11A may overlap the first side upper organic film 13A. The second side upper tapered surface 11B1 formed on the second side upper substrate 11B may overlap the second side upper organic film 13B. The third side upper tapered surface 11C1 formed on the third side upper substrate 11C may overlap the third side upper organic film 13C. The fourth side upper tapered surface 11D1 formed on the fourth side upper substrate 11D may overlap the fourth side upper organic film 13D. A resulting shape of the display device 100 formed by the perimeter extending along and around each of the upper tapered surfaces 11A1, 11B1, 11C1, and 11D1 and each of the upper organic films 13A, 13B, 13C, and 13D may include a tapered shape that is a reverse-tapered shape as compared to the tapered shape of the lower tapered surfaces.

On the first side surface 100A, the first side lower organic film 12A may extend toward and forms a portion of the first side surface 100A. An edge of the first side lower organic film 12A may protrude further toward the first side surface 100A than an edge of the first side lower tapered surface 10A1. On the second side surface 100B, the second side lower organic film 12B may extend toward and forms a portion of the second side surface 100B. An edge of the second side lower organic film 12B may protrude further toward the second side surface 100B than an edge of thethe second side lower tapered surface 10B1. On the third side surface 100C, the third side lower organic film 12C may include a protrusion that extends toward the third side surface 100C. The protrusion may extend further toward the third side surface 100C as compared to the third side lower tapered surface 10C. On the fourth side surface 100D, the fourth side lower organic film 12D may include a protrusion that extends toward the second side surface 100D. The protrusion may extend further toward the fourth side surface 100D compared to the fourth side lower tapered surface 10D.

On the first side surface 100A, the first side upper organic film 13A may include a protrusion that extends toward the second side surface 100A. The protrusion may extend further toward the first side surface 100A compared to the first side upper tapered surface 11A. On the second side surface 100B, the second side upper organic film 12B may include a protrusion that extends toward the second side surface 100B. The protrusion may extend protruding further toward the second side 100B surface as compared to the second side upper tapered surface 11B. On the third side surface 100C, the third side upper organic film 13C may include a protrusion that extends toward the second side surface 100C. The protrusion may extend further toward the third side surface 100C as compared to the third side upper tapered surface 11C. On the fourth side surface 100D, the fourth side upper organic film 13D may include a protrusion that extends toward the second side surface 100D. The protrusion may extend further toward the fourth side surface 100D as compared to the fourth side upper tapered surface 11D.

In some embodiments, on the first side surface 100A, the first side lower organic film 12A and the first side upper organic film 13A may be formed to be misaligned such that they not overlap each other in the thickness direction of the display device 100 when viewed from a cross-sectional view.

In some embodiments, on the second side surface 100B, the second side lower organic film 12B and the second side upper organic film 13B may be formed to overlap each other when viewed from a cross-sectional view. On the third side surface 100C, the third side lower organic film 12C and the third side upper organic film 13C may be formed to overlap each other when viewed from a cross-sectional view. On the fourth side surface 100D, the fourth side lower organic film 12D and the fourth side upper organic film 13D may be formed to overlap each other when viewed from a cross-sectional view.

As shown in FIGS. 5 and 7, the display device 100 may comprise a plurality of side surface coating layers 25, 26 disposed on the first to fourth side surfaces 100A, 100B, 100C, and 100D, respectively. The plurality of side surface coating layers may include a first side lower side surface coating layer 25A disposed on the first side lower substrate 10A, a second side lower side surface coating layer 25B disposed on the second side lower substrate 10B, a third side lower side surface coating layer 25C disposed on the third side lower substrate 10C, and a fourth side lower side surface coating layer 25D disposed on the fourth side lower substrate 10D. The display device 100 may further comprise a first side upper side surface coating layer 26A disposed on the first side upper substrate 11A, a second side upper side surface coating layer 26B disposed on the second side upper substrate 11B, a third side upper side surface coating layer 26C disposed on the third side upper substrate 11C, and a fourth side upper side surface coating layer 26D disposed on the fourth side upper substrate 11D. The side surface coating layers 25 and 26 may be formed to planarize the upper substrate 11 or the lower substrate 10. Therefore, it may be possible to reinforce the rigidity of the side surfaces of the display device.

The first side surfaces of the first side lower side surface coating layer 25A and the first side upper side surface coating layer 26A may be surfaces which are actually sawn or cut and may have flat cross sections. The second side surfaces of the second side lower side surface coating layer 25B and the second side upper side surface coating layer 26B may be surfaces which are actually sawn or cut and may have flat cross sections. The third side surfaces of the third side lower side surface coating layer 25C and the third side upper side surface coating layer 26C may be surfaces which are actually sawn or cut and may have flat cross sections. The fourth side surfaces of the fourth side lower side surface coating layer 25D and the fourth side upper side surface coating layer 26D may be surfaces which are actually sawn or cut and may have flat cross sections.

The lower side coating layers 25A, 25B may be disposed adjacent the end portions of the lower substrate 10. The end portions of the lower substrate 10 may be formed at an angle such that the end portion is tapered. The lower side coating layers 25A, 25B may be formed having a tapered portion that complements the end portion of the lower substrate. An upper surface of the lower side coating layers 25A, 25B may be disposed proximate a lower surface of the first etch stop layer 12A. In some embodiments, the upper surface of the lower side coating layers 25A, 25B may directly contact the lower surface of the first etch stop layer 12A.

As described with respect to the lower substrate 10, the upper substrate 11 may include a tapered end portion. Similarly, the upper side surface coating layers 26A, 26B may be formed having a tapered end portion that complements the tapered end portion of the upper substrate 11. An lower surface of the upper side coating layers 26A, 26B may be disposed proximate an upper surface of the second etch stop layer 13A. In some embodiments, the lower surface of the upper side coating layers 26A, 26B may directly contact the upper surface of the second etch stop layer 13A.

In some embodiments, each of the lower organic film 12 and the upper organic film 13 are etch-stop layers and may include an organic material which is strongly resistant to an etching solution. For example, the etch-stop layer may include at least one selected from the group consisting of a polyester-based polymer, a silicone-based polymer, an acrylic polymer, a polyolefin-based polymer, and copolymers thereof. However, the etch-stop layer is not necessarily limited thereto and may include any of various materials which are strongly resistant to the etching solution. Since polyimide has acid resistance and heat resistance, in some embodiments, the polyimide can be applied to high temperature processes for forming the circuit layer 14 and the light emitting element layer 16. The upper organic film 13 may be made of a black-based organic material to form a decoration line for marking or the like.

The circuit layer 14 may include data lines, pixel circuits connected to gate lines and power lines, a gate driving unit connected to the gate lines, and the like. The pixel circuit and the gate driving unit may include circuit elements such as a thin film transistor (TFT) and a capacitor. When a bending portion is formed in the display device 100, the circuit layer 14 may include lines such as data lines, gate lines, and power lines.

The light emitting element layer 16 may include an organic light emitting diode (OLED) driven by a driving element of the pixel circuit. The OLED may include an organic compound layer formed between an anode and a cathode. The organic compound layer may include a hole injection layer (HIL), a hole transport layer (HTL), an emission layer (EML), an electron transport layer (ETL), and an electron injection layer (EIL), but is not limited thereto. When a voltage is applied to the anode and cathode of the OLED, holes passing through the hole transport layer (HTL) and electrons passing through the electron transport layer (ETL) may move to the emission layer (EML) to form excitons, and, as a result, visible light may be emitted from the emission layer (EML). The light emitting element layer 16 may further include a color filter array for selectively transmitting light of red, green, or blue wavelengths.

The pad 23 may include an IC driver in which several drivers required for driving the display device 100 are integrated. For example, the pad 23 may include a chip on film (COF), a printed circuit board (PCB), or the like.

The light emitting element layer 16 and the circuit layer 14 may be covered with a protective layer not shown in the drawing. The protective layer and the encapsulation layer 18 may be formed of an inorganic film made of a glass, a metal, aluminum oxide (AlOx), or a silicon-based material or may be a structure in which organic films and inorganic films are stacked alternately. The inorganic film may block permeation of moisture or oxygen. The organic film may planarize a surface of the inorganic film. When the organic film and the inorganic film are stacked in multiple layers, a movement path of moisture or oxygen may become longer than that of a single layer, and thus the permeation of moisture/oxygen affecting the light emitting element layer 16 may be effectively blocked.

The color filter layer 22 may be disposed on the encapsulation layer 18. The color filter layer 22 may improve the outdoor visibility of the display device 100. The color filter layer 22 may reduce light reflected from the surface of the display device 100 and improve brightness by blocking light reflected from the metal of the circuit layer 14. The color filter layer 22 may be implemented as a polarizer or circular polarizer in which a linear polarizer and a phase retardation film are laminated. The touch sensor layer 21 and the color filter layer 22 may be omitted by a developer.

The bonding layer 19 may extend by being bent from at least a portion (e.g., the second side) of the remaining edge area (e.g., the second to fourth sides) except for the area where the pads 23 connected to the external circuit are formed, and may be disposed in contact with the lower organic film 12. In some embodiments, the bonding layer 19 may be disposed between the color filter layer 22 and the upper substrate 11 in the inner area of the first area 101 to fixedly bond the color filter layer 22 and the upper substrate 11. The bonding layer 19 may further be disposed between the lower organic film 12 and the upper organic film 13 at the second side of the outer area of the first area 101 to fixedly bond the lower substrate 10, on which the lower organic film 12 is formed, and the upper substrate 11, on which the upper organic film 13 is formed.

Although not shown in the figures, the lower substrate 10 may be removed at the boundary between the first area 101 and the second area 102, and the boundary may become the bending portion. The lower substrate 10 may be formed to expose the organic film positioned to overlap the bending portion to a back surface of the display device 100.

As shown in FIGS. 4, 5, and 7, a back surface coating layer 24 may be formed on the entire back surface of the lower substrate 10. The back surface coating layer 24 may be formed on the back of the lower substrate 10 such that it overlaps the first area 101. The back surface coating layer 24 may be formed to planarize the back surface of the lower substrate 10. The back surface coating layer 24 may be formed to overlap the first to fourth side lower side surface coating layers 25A, 25B, 25C, and 25D, respectively.

The back surface coating layer 24 may be formed using a material with good stretchability capable of preventing the degradation of rigidity when the lower substrate 10 of the display device 100 becomes thinner. The back surface coating layer 24 may be formed in a form of a reinforcement film capable of preventing the occurrence of scratches on the lower substrate 10.

The back surface coating layer 24 may be made of an organic material including, for example, a polyester-based polymer or an acrylic-based polymer.

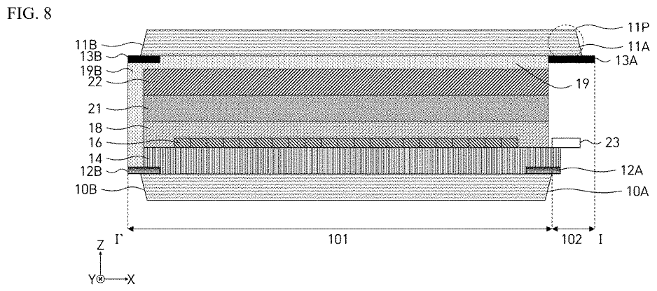

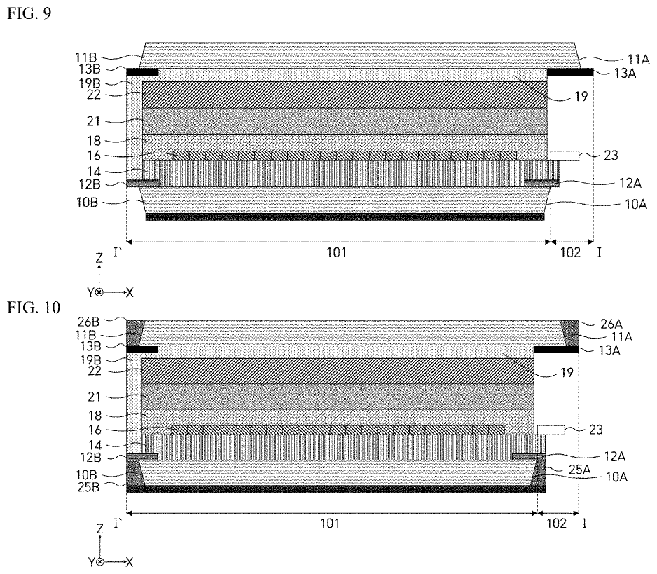

As shown in FIGS. 8 to 10, the upper substrate 11 may be larger than the lower substrate 10. The upper substrate 11 may include the first area 101 and the second area 102. For example, the pad 23 may be formed on the circuit layer 14 overlapping the second area 102. The first side upper organic film 13A and the first side lower organic film 12A may be disposed to be misaligned in the thickness direction of the display device. The upper substrate 11 may include a protrusion 11P of the upper substrate 11, which protrudes further toward the first side compared to the lower substrate 10. For example, the pad 23 may be disposed in the second area 102. According to such a borderless type display device, a bezel, which is a non-display area, can be reduced when viewed from the front of the display device 100. In addition, it is possible to make the product smaller and lighter.

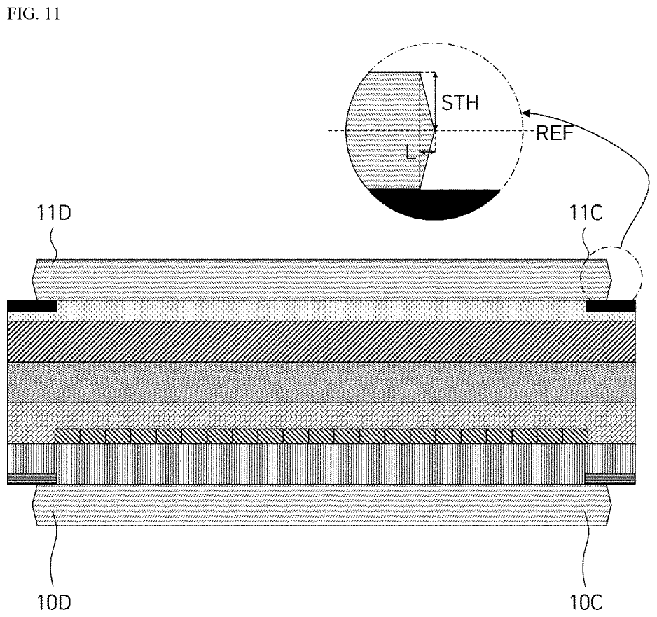

FIG. 11 is a cross-sectional view showing a substrate of the display device according to the embodiment of the present disclosure. Such a substrate can be applied and/or used in any of the above-described embodiments.

As shown in FIG. 11, an edge sidewall of the lower substrate 10 or the upper substrate 11 may be processed into a wedge type. A sidewall of a corner portion on which two sides of the lower substrate 10 or the upper substrate 11 meet may also be processed into a wedge type. The wedge type indicates a shape in which the tapered surfaces 10C, 10D, 11C, and 11D of each of a portion at half thickness of an upper portion or a portion at half thickness of a lower portion of the lower substrate 10 or the upper substrate 11 are symmetrical with respect to a thickness center REF of the lower substrate 10 or the upper substrate 11 when viewed from an edge cross section of the lower substrate 10 or the upper substrate 11. The thickness of the lower substrate 10 or the upper substrate 11 may gradually become thinner from the edge to the sidewall due to the vertically symmetrical tapered surfaces 10C, 10D, 11C, and 11D. An edge thickness STH of the lower substrate 10 or the upper substrate 11 may be inversely proportional to a distance L from the center.

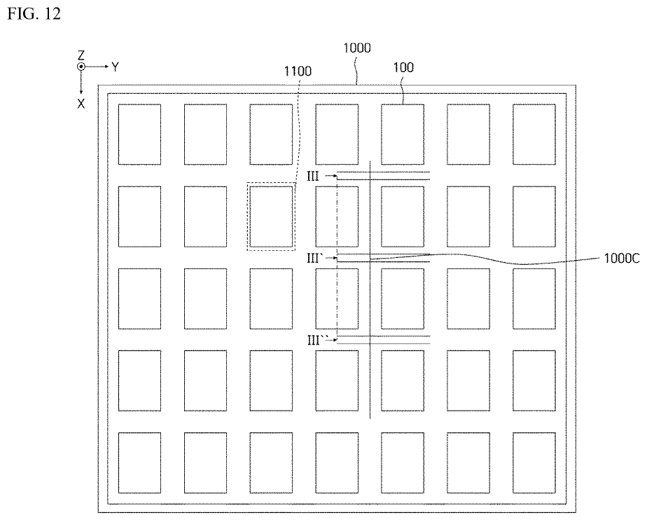

As shown in FIG. 12, the display device 100 may be formed by a process of forming a thin film in a plurality of cells CELL 1100 on a mother substrate (glass) 1000, which is a large glass substrate. As illustrated in FIG. 12, one cell 1100 indicates one display panel.

A plurality of display devices 100 may be manufactured simultaneously in a multi-panel process to reduce costs. First, the plurality of cells 1100 may be formed on the mother substrate 1000. After the plurality of cells 1100 are formed, a cutting line 1000c may be set on the mother substrate 1000. The cutting line 1000c may be marked by laser patterning, as will be described below. As illustrated, only a portion of the shown cutting line 1000c is shown. Each of the cells 1100 may be separated (or cut) from the mother substrate 1000 with respect to the cutting line 1000c.

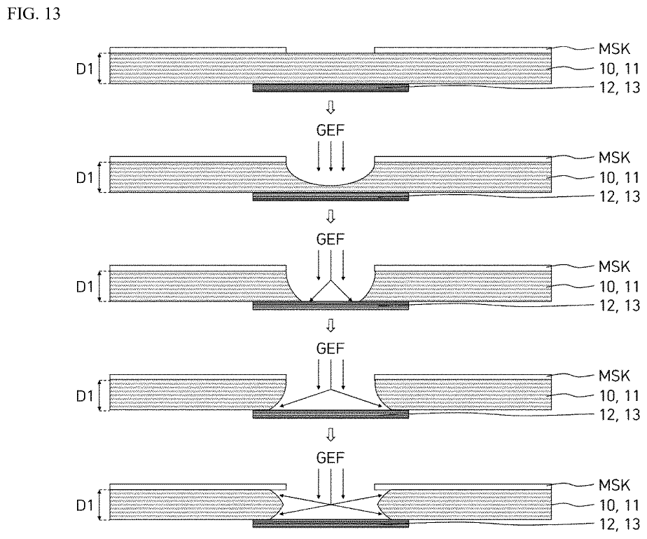

As shown in FIG. 13, a mask MSK may be disposed on one surfaces of the substrates 10 and 11, and the organic films 12 and 13 may be disposed on the other surfaces of the substrates 10 and 11. In some embodiments. the circuit layer and the organic light emitting layer are disposed on the organic films 12 and 13, however, as illustrated, they are omitted for convenience of description. The mask MSK and the organic films 12 and 13 may be organic films applied on or laminated to the substrates 10 and 11. The organic films 12 and 13 may function as etch stoppers in the etching process. The mask MSK may include an opening through which the substrates 10 and 11 are exposed to a glass etching fluid GEF. The opening of the mask MSK may be formed by laser patterning. Shapes, thicknesses, distances, and the like of patterns to be formed on the substrates 10 and 11 may be determined depending on shapes and distances of the openings and an etching process time. The mask MSK may be removed after the etching process. The substrates 10 and 11 may be etched by a method of spraying the glass etching fluid GEF on the substrates 10 and 11, to which the mask MSK is laminated, or a method of dipping the substrates 10 and 11 into the glass etching fluid GEF.

The glass etching fluid GEF may be supplied onto the substrates 10 and 11 through the opening of the mask MSK. The substrates 10 and 11 exposed through the opening of the mask MSK may start to be etched in reaction to the glass etching fluid GEF.

The glass exposed to the glass etching fluid GEF may be etched to form the openings in the substrates 10 and 11, and as an etching process time elapses, a depth of the opening may be increased.

As the etching process time further increases in the etching process, the glass etching fluid GEF enters between the substrates 10 and 11 and the organic films 12 and 13 and between the substrates 10 and 11 and the mask MSK so that the tapered surfaces may be formed on the sidewall substrate overlapping the opening in the thickness direction of the substrate.

As the etching process time increases, the tapered surfaces start to be formed at the edges of the substrates 10 and 11 exposed to the glass etching fluid GEF, and as the process time further increases, the tapered surfaces may extend. When the lower surface of the substrate 10 is exposed to the glass etching fluid GEF in the etching process, the thickness of the substrate 10 may decrease, and thus the tapered surfaces may extend (see for example L in FIG. 11). The etching process may be stopped when the thickness and cross-sectional wedge shape of the glass substrate reach predetermined design values.

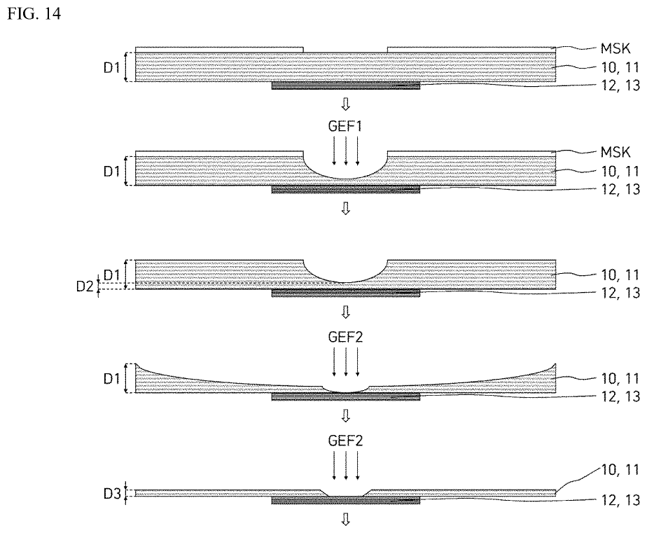

As shown in FIG. 14, the substrates 10 and 11 exposed to a primary glass etching fluid GEF1 may be etched to form the openings in the substrates 10 and 11.

The etching process may be stopped after the opening with a predetermined size is formed. At this time, the mask MSK may be removed. The substrates 10 and 11 may have a thickness of D1 before performing a primary etching process and may have a thickness of D2 in the opening after the opening is formed. In an example embodiment, D1 may be in the range of 400 μm to 600 μm, and the thickness D2 of the opening may be in the range of 200 μm to 400 μm. An etched thickness (D1-D2) at the opening may be 200 μm or more.

After the mask MSK is removed, the substrates 10 and 11 may be exposed to a secondary glass etching fluid GEF2. With the removal of the mask, the entirety of the substrates 10 and 11 may be etched to reduce the overall thickness. After performing a secondary etching process, the thicknesses of the substrates 10 and 11 may be in the range of 100 μm to 300 μm. A thickness of the substrates 10 and 11 etched by the secondary glass etching fluid GEF2 may be at least 300 μm and may be greater than the thickness D2 of the opening. The organic films 12 and 13 may function as etch stoppers in preparation for a case in which etching occurs more than necessary. A hole including the tapered surface formed by the secondary etching process may be formed in the substrates 10 and 11 corresponding to portions in which the openings are formed. The hole may be formed to overlap the organic films 12 and 13.

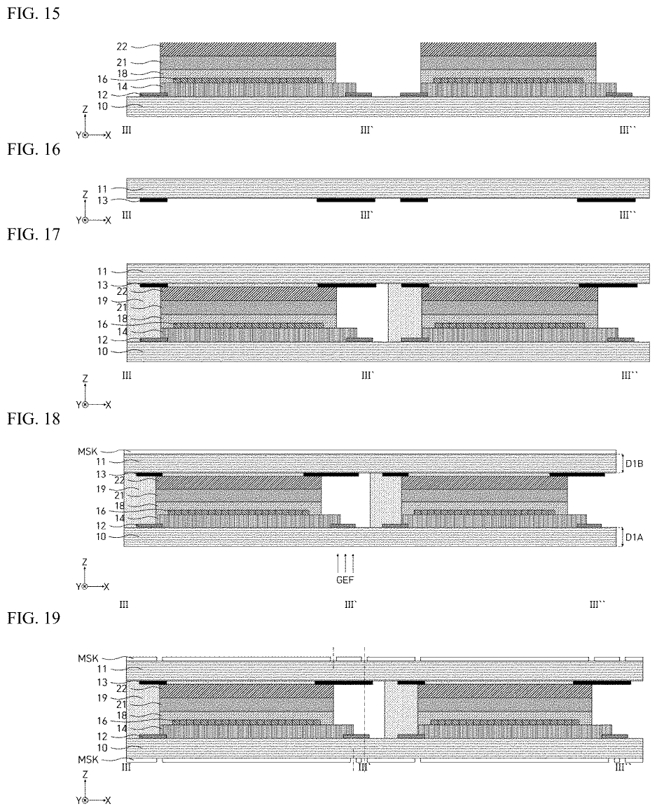

As shown in FIG. 15, the lower organic film 12, the circuit layer 14, the light emitting element layer 16, and the encapsulation layer 18 may be formed on the lower mother substrate 10. In some embodiments, the lower mother substrate 10 may further include the touch sensor layer 21 and the color filter layer 22.

As shown in FIG. 16, the upper organic film 13 may be formed on the upper mother substrate 11.

As shown in FIG. 17, the lower mother substrate 10 and the upper mother substrate 11 may be laminated using the bonding layer 19. The bonding layer 19 may not be applied on a portion in which the pad is positioned after cutting, may be formed to laminate the upper mother substrate 11 and the lower mother substrate 10 in a portion on which the light emitting element layer is not disposed, and laminate the color filter layer 22 and the upper mother substrate 11 (as shown) in a portion on which the light emitting element layer is disposed.

As shown in FIG. 18, before performing the process for marking the cutting line, a process of adjusting the thicknesses of the upper substrate 11 and/or the lower substrate 10 may be performed. For example, to reduce the thickness of the lower substrate 10, the mask MSK may be formed on the upper substrate 11, and the glass etching fluid GEF may be sprayed on the lower substrate 10. In some embodiments, before laminated and etched, the upper mother substrate 11 and the lower mother substrate 10 may be formed to have substantially the same thickness. In this case, there is may be an economic advantage in that the manufacturing cost of the display device can be reduced because the mother substrate can be used for both substrates. In addition, to adjust the thickness later, if necessary (for example), a process of separately spraying the etching fluid on the lower substrate 10 may be added, and thus there is an advantage in that the thickness of the substrate may be appropriately adjusted afterwards by a developer.

In some embodiments, after performing the etching process for adjusting the thickness of the substrate, the lower mother substrate 10 may have a thickness of D1A, and the upper mother substrate 11 may have a thickness of D1B.

As shown in FIG. 19, the mask MSK may be formed on each of the upper mother substrate 11 and the lower mother substrate 10. The mask MSK may be disposed on the upper surface of the upper mother substrate 11. The mask MSK may be disposed on the lower surface of the lower mother substrate 10. Thereafter, the opening may be formed in the mask MSK through the laser patterning process as described above. The formed opening may become the above-described cutting line.

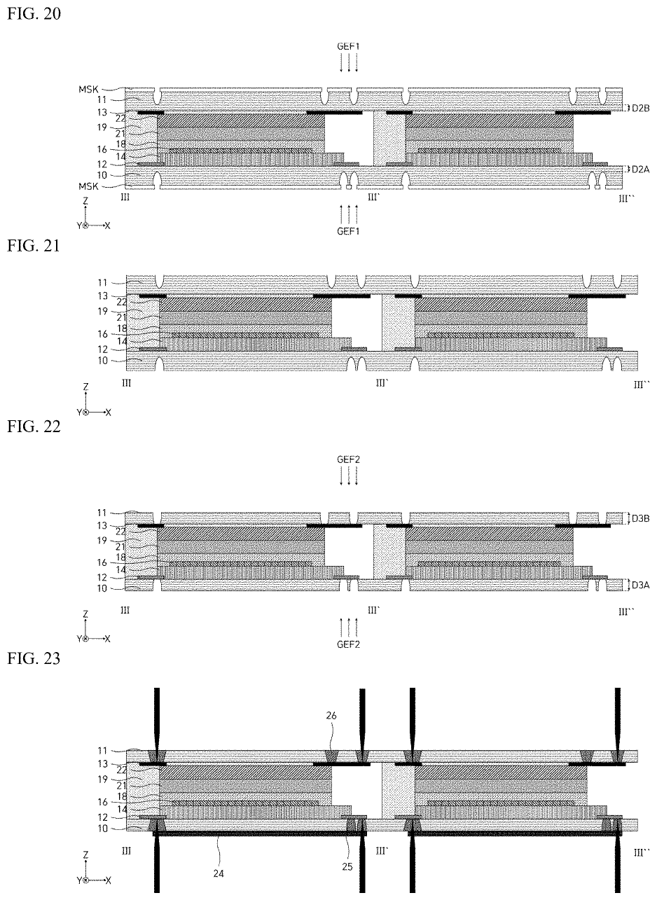

As shown in FIG. 20, the primary glass etching fluid GEF1 may be sprayed into openings formed in the mask MSK. When the etching time is appropriately adjusted, the etching process may be performed so that the thickness of the upper mother substrate overlapping the opening is D2B and the thickness of the lower mother substrate is D2A. Holes may be formed in portions of the substrates 10 and 11 that overlap the openings of the mask MSK. In some embodiments, since the thickness of the upper substrate and the thickness of the lower substrate may be formed differently as shown in FIG. 18, D2A may differ from D2B.

As shown in FIG. 21, the mask disposed on the upper mother substrate 11 and the mask disposed on the lower mother substrate 10 may be removed.

As shown in FIG. 22, the secondary glass etching fluid GEF2 may be sprayed on each of the upper mother substrate 11 and the lower mother substrate 10. At this time, the openings, which have already been etched by the primary glass etching fluid GEF1 and of which the thicknesses have been adjusted, may be continuously etched to become holes. The hole may have a tapered surface due to the property of etching or the like, but is not limited thereto.

In some embodiments, a thickness (D1-D3) to be formed by etching with the secondary glass etching fluid GEF2 may be greater than the thickness D2 of the opening of which the thickness has been adjusted by the primary glass etching fluid GEF1. A thickness D3B of the upper mother substrate 11 remaining after the etching process is performed may be 500 μm or less, preferably, 300 μm or less, or 200 μm or less. A thickness D3A of the lower mother substrate 10 remaining after the etching process is performed may be 500 μm or less, 300 μm or less, or preferably, 200 μm or less.

In some embodiments, the thickness D3A of the lower mother substrate 10 and the thickness D3B of the upper mother substrate 11 remaining after the etching process is performed may be different. The thickness D3A of the lower mother substrate 10 may be substantially the same as the thickness of the lower substrate of the display device according to the embodiment of the present disclosure after performing the cutting process. The thickness D3B of the upper mother substrate 11 may be substantially the same as the thickness of the upper substrate of the display device according to the embodiment of the present disclosure after performing the cutting process. Therefore, the thickness of the upper substrate and the thickness of the lower substrate of the display device according to the embodiment may be different.

As shown in FIG. 23, the back surface coating layer 24 may be formed on the back surface of the lower mother substrate 10. Alternatively, in some embodiments, the side surface coating layers 25 and 26 may be formed on the tapered surfaces formed by the secondary glass etching fluid GEF2.

The upper mother substrate 11 and the lower mother substrate 10 may then be cut. Primary cutting may be performed on a portion in which the cutting lines of the upper substrate 11 and the lower substrate 10 overlap each other to distinguish the display device.

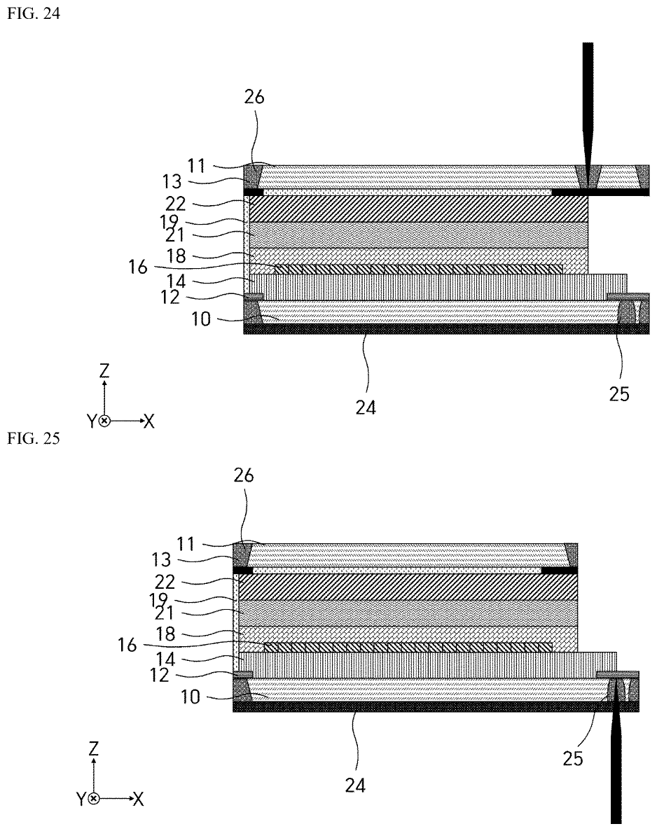

As shown in FIG. 24, then, secondary cutting may be performed on the 1^{st} side portion of the upper substrate 11 to open a portion in which the pad is positioned without the bonding layer.

As shown in FIG. 25, in the manufacturing process of the display device, an auto-probe test for performing electrical test (such as a line short circuit and on-off test) of the entirety of the display panel may be performed. The auto-probe test may be performed through a process of applying an electrical test signal after allowing a test needle to be in contact with an auto probe test pad (hereinafter referred to as “AP pad”) formed on the display panel. The test signal may be applied to the display device through test lines connected to the AP pads. In some embodiments, the test lines may be connected to bonding pads to which a chip on film (COF) is attached. The AP pad may be removed through a cutting process using a laser in order for a narrow bezel after the auto-probe test.

Tertiary cutting may be performed on the 1^{st} side portion of the lower substrate 10. A portion cut by the tertiary cutting may include the AP pad removed after the above-described auto-probe test.

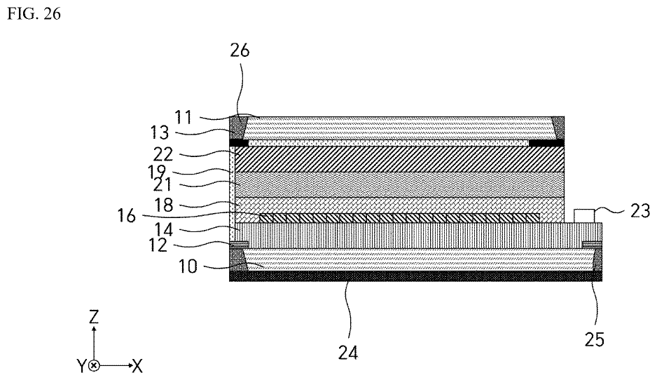

As shown in FIG. 26, then, the pad 23 may be attached to the first side. According to the some embodiments, by enabling a laminating process of an upper substrate instead of a cover glass and a mother substrate and cell separation, it is possible to manufacture a display device including the upper substrate with different rigidity for each application.

According to the some embodiments, it is possible to manufacture a display device from a mother substrate by selective etching the mother substrate according to process optimization.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

Example embodiments of the present disclosure may be described as follows.

In one or more example embodiments, a display device having a first side opposite a second side, the display device may include a first substrate having an end portion, a first etch-stop layer having an end portion disposed on the first substrate, a circuit layer and a light emitting element layer disposed on the first etch-stop layer, a second substrate disposed on the light emitting element layer, and a second etch-stop layer disposed between the second substrate and the light emitting element layer. The end portion of the first etch-stop layer may protrude further in a direction of the first side than the end portion of the first substrate.

In some example embodiments, the display device of claim may further include a coating layer disposed on the end portion the substrate.

In some example embodiments, the second substrate may be positioned above the second etch-stop layer in a vertical direction.

In some example embodiments, the end portion of the substrate may be tapered, and an end portion of the coating layer may be tapered such that the end portion of the coating layer corresponds to the end portion of the substrate.

In some example embodiments, the display device may further include a first side surface and a second side surface that face each other, a third side surface and a fourth side surface that face each other. The first substrate may include a 5^{th} side portion and a 6^{th} side portion that are disposed on the first side surface and the second side surface, respectively, and face each other. A 7^{th} side portion and an 8^{th} side portion may be disposed on the third side surface and the fourth side surface, respectively, and face each other. The second substrate may include a 9^{th} side portion and a 10^{th} side portion that are disposed on the first side surface and the second side surface, respectively, and face each other. An 11^{th} side portion and a 12^{th} side portion may be disposed on the third side surface and the fourth side surface, respectively, and face each other.

In some example embodiments, the first etch-stop layer may include a 13^{th} side portion and a 14^{th} side portion that are disposed on the first side surface and the second side surface, respectively, and face each other. A 15^{th} side portion and a 16^{th} side portion may be disposed on the third side surface and the fourth side surface, respectively, and face each other.

In some example embodiments, the second etch-stop layer may include a 17^{th} side portion and an 18^{th} side portion that are disposed on the first side surface and the second side surface, respectively, and face each other. A 19^{th} side portion and a 20^{th} side portion may be disposed on the third side surface and the fourth side surface, respectively, and face each other.

In some example embodiments, the 5^{th} side portion and the 13^{th} side portion may be disposed to overlap each other in a thickness direction. The 6^{th} side portion and the 14^{th} side portion may be disposed to overlap each other in the thickness direction. The 7^{th} side portion and the 15^{th} side portion may be disposed to overlap each other in the thickness direction. The 8^{th} side portion and the 16^{th} side portion may be disposed to overlap each other in the thickness direction.

In some example embodiments, the 9^{th} side portion and the 17^{th} side portion may be disposed to overlap each other in the thickness direction. The 10^{th} side portion and the 18^{th} side portion may be disposed to overlap each other in the thickness direction. The 11^{th} side portion and the 19^{th} side portion may be disposed to overlap each other in the thickness direction. The 12^{th} side portion and the 20^{th} side portion may be disposed to overlap each other in the thickness direction.

In some example embodiments, the 13^{th} side portion and the 17^{th} side portion may be positioned such that they are misaligned in a thickness direction. The 14^{th} side portion and the 18^{th} side portion may be disposed to overlap each other in the thickness direction. The 15^{th} side portion and the 19^{th} side portion may be disposed to overlap each other in the thickness direction. The 16^{th} side portion and the 20^{th} side portion may be disposed to overlap each other in the thickness direction.

In some example embodiments, the first etch-stop layer may have a ring structure and may be disposed to overlap an area disposed outside the first substrate. The second etch-stop layer may have a ring structure and is disposed to overlap an area disposed outside the second substrate.

In some example embodiments, the first etch-stop layer may have a planar structure and may be disposed to overlap an area disposed inside the first substrate.

In some example embodiments, the first substrate includes a first area and a second area. The second substrate and the second etch-stop layer may be disposed on the first area, and the first etch-stop layer may be disposed on the first area and the second area.

In some example embodiments, the 13^{th} side portion may be disposed on the second area, and the 17^{th} side portion may be disposed on the first area.

In some example embodiments the display device may further include a bonding layer disposed between the second substrate and the first substrate.

In some example embodiments, the bonding layer includes a 21^{st} side portion disposed between the 18^{th} side portion and the 14^{th} side portion.

In some example embodiments, a thickness of the 21^{st} side portion is greater than a thickness of the bonding layer and disposed to overlap the light emitting element layer.

In some example embodiments the display device further includes a back surface coating layer formed on a back surface of the first substrate.

In some example embodiments the display device further includes a first side surface coating layer disposed at a first side and disposed at the 5^{th} side portion so as to overlap the 13^{th} side portion, a first side surface coating layer disposed at a second side and disposed at the 6^{th} side portion so as to overlap the 14^{th} side portion, a first side surface coating layer disposed at a third side and disposed at the 7^{th} side portion so as to overlap the 15^{th} side portion, and a first side surface coating layer disposed at a fourth side and disposed at the 8^{th} side portion so as to overlap the 16^{th} side portion.

In some example embodiments, the 13^{th} side portion includes a protrusion protruding toward the first side surface. The 14^{th} side portion may include a protrusion protruding toward the second side surface. The 15^{th} side portion may include a protrusion protruding toward the third side surface. The 16^{th} side portion may include a protrusion protruding toward the fourth side surface.

In some example embodiments, the 17^{th} side portion may include a protrusion protruding toward the first side surface. The 18^{th} side portion may include a protrusion protruding toward the second side surface. The 19^{th} side portion may include a protrusion protruding toward the third side surface. The 20^{th} side portion may include a protrusion protruding toward the fourth side surface.

In some example embodiments, a size of the second substrate is greater than a size of the first substrate.

In some example embodiments, the 9^{th} side portion may include a protrusion protruding toward the 5^{th} side portion.

In one or more example embodiments, a display device having a first side opposite a second side, the display device including a first substrate having an end portion, a first etch-stop layer having an end portion disposed on the first substrate. a circuit layer and a light emitting element layer disposed on the first etch-stop layer, a second substrate disposed on the light emitting element layer, a second etch-stop layer disposed between the second substrate and the light emitting element layer, and a coating layer disposed the end portion of the first substrate and the end portion of the second substrate. The end portion of the first etch-stop layer may protrudes further in a direction of the first side than the end portion of the first substrate.

As set forth above, specific example embodiments of the present disclosure have been described in more detail with reference to the accompanying drawings. However, the present disclosure is not limited to the foregoing example embodiments, but a variety of modifications are possible without departing from the principle of the present disclosure. Thus, the foregoing example embodiments disclosed herein should be interpreted as being illustrative, while not being limiting, of the principle of the present disclosure, and the scope of the present disclosure is not limited to the foregoing example embodiments. Therefore, the foregoing example embodiments should not be construed as being exhaustive in any aspects.

It will be apparent to those skilled in the art that various modifications and variations can be made in the present disclosure without departing from the spirit or scope of the disclosure. Thus, it is intended that the present disclosure cover such modifications and variations of this disclosure.

What is claimed is:

1. A display device having a first side opposite a second side, the display device comprising:
a first substrate having an end portion;
a first etch-stop layer having an end portion disposed on the first substrate;
a circuit layer and a light emitting element layer disposed on the first etch-stop layer;
a second substrate disposed on the light emitting element layer; and
a second etch-stop layer disposed between the second substrate and the light emitting element layer, and
wherein the end portion of the first etch-stop layer protrudes further in a direction of the first side than the end portion of the first substrate.

2. The display device of claim 1, further comprising a coating layer disposed on the end portion the substrate.

3. The display device of claim 1, wherein the second substrate is positioned above the second etch-stop layer in a vertical direction.

4. The display device of claim 2, wherein the end portion of the substrate is tapered, and
wherein an end portion of the coating layer is tapered such that the end portion of the coating layer corresponds to the end portion of the substrate.

5. The display device of claim 1, further comprising:
a first side surface and a second side surface that face each other; and
a third side surface and a fourth side surface that face each other,
wherein the first substrate comprises:
a 5^{th} side portion and a 6^{th} side portion that are disposed on the first side surface and the second side surface, respectively, and face each other; and
a 7^{th} side portion and an 8^{th} side portion that are disposed on the third side surface and the fourth side surface, respectively, and face each other, and
the second substrate comprises:
a 9^{th} side portion and a 10^{th} side portion that are disposed on the first side surface and the second side surface, respectively, and face each other; and
an 11^{th} side portion and a 12^{th} side portion that are disposed on the third side surface and the fourth side surface, respectively, and face each other.

6. The display device of claim 5, wherein the first etch-stop layer comprises:
a 13^{th} side portion and a 14^{th} side portion that are disposed on the first side surface and the second side surface, respectively, and face each other; and
a 15^{th} side portion and a 16^{th} side portion that are disposed on the third side surface and the fourth side surface, respectively, and face each other.

7. The display device of claim 6, wherein the second etch-stop layer comprises:
a 17^{th} side portion and an 18^{th} side portion that are disposed on the first side surface and the second side surface, respectively, and face each other; and
a 19^{th} side portion and a 20^{th} side portion that are disposed on the third side surface and the fourth side surface, respectively, and face each other.

8. The display device of claim 7, wherein the 5^{th} side portion and the 13^{th} side portion are disposed to overlap each other in a thickness direction,
wherein the 6^{th} side portion and the 14^{th} side portion are disposed to overlap each other in the thickness direction,
wherein the 7^{th} side portion and the 15^{th} side portion are disposed to overlap each other in the thickness direction, and
wherein the 8^{th} side portion and the 16^{th} side portion are disposed to overlap each other in the thickness direction.

9. The display device of claim 8, wherein the 9^{th} side portion and the 17^{th} side portion are disposed to overlap each other in the thickness direction,
wherein the 10^{th} side portion and the 18^{th} side portion are disposed to overlap each other in the thickness direction,
wherein the 11^{th} side portion and the 19^{th} side portion are disposed to overlap each other in the thickness direction, and
wherein the 12^{th} side portion and the 20^{th} side portion are disposed to overlap each other in the thickness direction.

10. The display device of claim 7, wherein the 13^{th} side portion and the 17^{th} side portion are positioned such that they are misaligned in a thickness direction,
wherein the 14^{th} side portion and the 18^{th} side portion are disposed to overlap each other in the thickness direction,
wherein the 15^{th} side portion and the 19^{th} side portion are disposed to overlap each other in the thickness direction, and
wherein the 16^{th} side portion and the 20^{th} side portion are disposed to overlap each other in the thickness direction.

11. The display device of claim 7, wherein the first etch-stop layer has a ring structure and is disposed to overlap an area disposed outside the first substrate, and
the second etch-stop layer has a ring structure and is disposed to overlap an area disposed outside the second substrate.

12. The display device of claim 7, wherein the first etch-stop layer has a planar structure and is disposed to overlap an area disposed inside the first substrate.

13. The display device of claim 7, wherein the first substrate comprises a first area and a second area,
wherein the second substrate and the second etch-stop layer are disposed on the first area, and
wherein the first etch-stop layer is disposed on the first area and the second area.

14. The display device of claim 13, wherein the 13^{th} side portion is disposed on the second area, and
wherein the 17^{th} side portion is disposed on the first area.

15. The display device of claim 7, further comprising a bonding layer disposed between the second substrate and the first substrate.

16. The display device of claim 15, wherein the bonding layer comprises a 21^{st} side portion disposed between the 18^{th} side portion and the 14^{th} side portion.

17. The display device of claim 16, wherein a thickness of the 21^{st} side portion is greater than a thickness of the bonding layer and disposed to overlap the light emitting element layer.

18. The display device of claim 7, further comprising a back surface coating layer formed on a back surface of the first substrate.

19. The display device of claim 7, further comprising:
a first side surface coating layer disposed at a first side and disposed at the 5^{th} side portion so as to overlap the 13^{th} side portion;
a first side surface coating layer disposed at a second side and disposed at the 6 side portion so as to overlap the 14th side portion;
a first side surface coating layer disposed at a third side and disposed at the 7th side portion so as to overlap the 15th side portion; and
a first side surface coating layer disposed at a fourth side and disposed at the 8th side portion so as to overlap the 16th side portion.

20. The display device of claim 7, wherein the 13^{th} side portion comprises a protrusion protruding toward the first side surface,
wherein the 14^{th} side portion comprises a protrusion protruding toward the second side surface,
wherein the 15^{th} side portion comprises a protrusion protruding toward the third side surface, and
wherein the 16^{th} side portion comprises a protrusion protruding toward the fourth side surface.

21. The display device of claim 20, wherein the 17^{th} side portion comprises a protrusion protruding toward the first side surface,
wherein the 18^{th} side portion comprises a protrusion protruding toward the second side surface,
wherein the 19^{th} side portion comprises a protrusion protruding toward the third side surface, and
wherein the 20^{th} side portion comprises a protrusion protruding toward the fourth side surface.

22. The display device of claim 5, wherein a size of the second substrate is greater than a size of the first substrate.

23. The display device of claim 22, wherein the 9^{th} side portion comprises a protrusion protruding toward the 5^{th} side portion.

24. A display device having a first side opposite a second side, the display device comprising:
a first substrate having an end portion;
a first etch-stop layer having an end portion disposed on the first substrate;
a circuit layer and a light emitting element layer disposed on the first etch-stop layer;
a second substrate disposed on the light emitting element layer; and
a second etch-stop layer disposed between the second substrate and the light emitting element layer,
a coating layer disposed the end portion of the first substrate and the end portion of the second substrate, and
wherein the end portion of the first etch-stop layer protrudes further in a direction of the first side than the end portion of the first substrate.
